(19) United States
(12) Patent Application Publication
(10) Pub. No.: US 2025/0233064 A1
(43) Pub. Date: Jul. 17, 2025

(54) INTEGRATED CAPACITOR SHEET, INTERPOSER, AND SEMICONDUCTOR ELEMENT

(71) Applicant: Murata Manufacturing Co., Ltd., Kyoto (JP)

(72) Inventors: Tomoyuki ASHIMINE, Kyoto (JP); Takuo WAKAOKA, Kyoto (JP); Hiroshi NAKAGAWA, Kyoto (JP); Frederic VOIRON, Kyoto (JP); Ryo KASAI, Kyoto (JP); Teiji YAMAMOTO, Kyoto (JP)

(21) Appl. No.: 19/097,912

(22) Filed: Apr. 2, 2025

Related U.S. Application Data
(63) Continuation of application No. PCT/JP2023/022744, filed on Jun. 20, 2023.

(30) Foreign Application Priority Data
Nov. 28, 2022 (JP) 2022-189170

(51) Int. Cl. H01L 23/522; H01L 23/498; H10D 1/68

(52) U.S. Cl. CPC H01L 23/5223; H01L 23/49827; H10D 1/716

(57) ABSTRACT

An integrated capacitor sheet including a conductor layer, and a porous layer provided on the conductor layer, in which the porous layer includes a capacitor portion having a structure of metal layer-dielectric layer-metal layer included in a porous structure of the porous layer, a through-hole portion in which the porous structure of the porous layer is filled with a conductor, and a porous insulating portion provided around the through-hole portion and in which the porous structure is not filled with the conductor, and the conductor layer includes a metal conductor, a first via portion that penetrates a metal conductor directly below the through-hole portion and is connected to the through-hole portion, and a first insulating portion that is provided around the first via portion and insulates the first via portion and the metal conductor.

### CROSS REFERENCE TO RELATED APPLICATION

This is a continuation of International Application No. PCT/JP2023/022744 filed on Jun. 20, 2023 which claims priority from Japanese Patent Application No. 2022-189170 filed on Nov. 28, 2022. The contents of these applications are incorporated herein by reference in their entireties.

### BACKGROUND OF THE DISCLOSURE

### Field of the Disclosure

The present disclosure relates to an integrated capacitor sheet, an interposer, and a semiconductor element.

### Description of the Related Art

As a typical capacitor element used in a semiconductor integrated circuit, for example, a metal insulator metal (MIM) capacitor is known. The MIM capacitor is a capacitor having a parallel plate-type structure in which an insulator is interposed between a lower electrode and an upper electrode.

Patent Document 1 discloses a laminated semiconductor device package in which logic is mounted on one surface of a substrate, a capacitor is mounted on the other surface of the substrate, and the logic and the capacitor are electrically connected to each other. In addition, it is disclosed that the capacitor is sealed with an insulator, and the insulator is provided with a through-hole filled with metal.

Patent Document 2 describes a capacitor structure including a substrate, a conductive layer on the substrate, and a porous layer on the conductive layer. The porous layer is said to have a first part provided with a conductor and a second part having an MIM capacitor structure.
Patent Document 1: International Publication No. WO 2016/099523
Patent Document 2: European Patent Application Publication No. 4009340

### BRIEF SUMMARY OF THE DISCLOSURE

With the structure described in Patent Document 1, since there is a package substrate between the logic and the capacitor, there are problems in that a distance between the logic and the capacitor is long, the ESL is high, and the impedance characteristics in a high frequency region are insufficient.

In addition, with the structure of Patent Document 2, there is a problem that the MIM capacitor structure and the power supply line on the substrate side cannot be integrated.

The present disclosure is made to solve the above-described problems, and a possible benefit thereof is to provide an integrated capacitor sheet, which can have a structure in which a distance between a semiconductor component, such as logic, and a capacitor portion is shortened to improve the impedance characteristics in a high frequency region, and allow a conductor provided on a porous layer having a capacitor structure to be extended in a thickness direction and integrated with a power supply line on a substrate side.

An integrated capacitor sheet of the present disclosure includes a conductor layer, and a porous layer provided on the conductor layer, in which the porous layer includes a capacitor portion having a structure of metal layer-dielectric layer-metal layer included in a porous structure of the porous layer, a through-hole portion in which the porous structure of the porous layer is filled with a conductor, and a porous insulating portion provided around the through-hole portion and in which the porous structure is not filled with the conductor, and the conductor layer includes a metal conductor, a first via portion that penetrates the metal conductor directly below the through-hole portion and is connected to the through-hole portion, and a first insulating portion that is provided around the first via portion and insulates the first via portion and the metal conductor.

An interposer of the present disclosure includes the integrated capacitor sheet of the present disclosure, and a rewiring layer disposed on at least one of main surfaces of the integrated capacitor sheet.

A semiconductor element of the present disclosure includes at least the integrated capacitor sheet of the present disclosure and a semiconductor portion in an integrated manner.

According to the present disclosure, it is possible to provide an integrated capacitor sheet, which can have a structure in which a distance between a semiconductor component, such as logic, and a capacitor portion is shortened to improve the impedance characteristics in a high frequency region, and allow a conductor provided on a porous layer having a capacitor structure to be extended in a thickness direction and integrated with a power supply line on a substrate side.

### BRIEF DESCRIPTION OF THE SEVERAL VIEWS OF THE DRAWINGS

FIG. 1 is a cross-sectional view schematically illustrating an example of an integrated capacitor sheet according to Embodiment 1 of the present disclosure.

FIG. 2A is an enlarged cross-sectional view of a capacitor portion.

FIG. 2B is an enlarged cross-sectional view of a through-hole portion.

FIG. 2C is an enlarged cross-sectional view of a porous insulating portion.

FIG. 3 is a cross-sectional view schematically illustrating an example of an integrated capacitor sheet according to Embodiment 2 of the present disclosure.

FIG. 4 is a cross-sectional view schematically illustrating an example of an integrated capacitor sheet according to Embodiment 3 of the present disclosure.

FIG. 5 is a cross-sectional view schematically illustrating an example of an integrated capacitor sheet according to Embodiment 4 of the present disclosure.

FIG. 6 is a cross-sectional view schematically illustrating an example of an integrated capacitor sheet according to Embodiment 5 of the present disclosure.

FIG. 7 is a cross-sectional view schematically illustrating an example of an integrated capacitor sheet according to Embodiment 6 of the present disclosure.

FIG. 8 is a cross-sectional view schematically illustrating an example of an integrated capacitor sheet according to Embodiment 7 of the present disclosure.

FIG. 9 is a cross-sectional view schematically illustrating an example of an integrated capacitor sheet according to Embodiment 8 of the present disclosure.

FIG. 10 is an enlarged view of a portion including a region A and a region B surrounded by a dotted line in FIG. 6.

FIG. 11 is a cross-sectional view schematically illustrating an example of an interposer of the present disclosure.

FIG. 12 is an enlarged view of a portion including a region C surrounded by a dotted line in FIG. 11.

FIG. 13A is a step diagram schematically illustrating an example of a manufacturing step for the integrated capacitor sheet.

FIG. 13B is a step diagram schematically illustrating an example of a manufacturing step for the integrated capacitor sheet.

FIG. 13C is a step diagram schematically illustrating an example of a manufacturing step for the integrated capacitor sheet.

FIG. 13D is a step diagram schematically illustrating an example of a manufacturing step for the integrated capacitor sheet.

FIG. 13E is a step diagram schematically illustrating an example of a manufacturing step for the integrated capacitor sheet.

FIG. 14A is a step diagram schematically illustrating an example of a manufacturing step for the integrated capacitor sheet and the interposer.

FIG. 14B is a step diagram schematically illustrating an example of a manufacturing step for the integrated capacitor sheet and the interposer.

FIG. 14C is a step diagram schematically illustrating an example of a manufacturing step for the integrated capacitor sheet and the interposer.

FIG. 14D is a step diagram schematically illustrating an example of a manufacturing step for the integrated capacitor sheet and the interposer.

FIG. 14E is a step diagram schematically illustrating an example of a manufacturing step for the integrated capacitor sheet and the interposer.

FIG. 14F is a step diagram schematically illustrating an example of a manufacturing step for the integrated capacitor sheet and the interposer.

FIG. 14G is a step diagram schematically illustrating an example of a manufacturing step for the integrated capacitor sheet and the interposer.

FIG. 15 is a cross-sectional view schematically illustrating a use example of the integrated capacitor sheet and the interposer.

FIG. 16 is a cross-sectional view schematically illustrating another use example of the integrated capacitor sheet and the interposer.

FIG. 17 is a cross-sectional view schematically illustrating another use example of the integrated capacitor sheet and the interposer.

FIG. 18 is a cross-sectional view schematically illustrating another use example of the integrated capacitor sheet and the interposer.

FIG. 19 is a cross-sectional view schematically illustrating an example of a semiconductor element of the present disclosure.

### DETAILED DESCRIPTION OF THE DISCLOSURE

Hereinafter, the integrated capacitor sheet, the interposer, and the semiconductor element of the present disclosure will be described.

However, the present disclosure is not limited to the following configurations, and can be applied after being appropriately modified without changing the gist of the present disclosure. Combinations of two or more separate preferred configurations of the present disclosure, which will be described below, are also part of the present disclosure.

Each of the embodiments described below is merely an example, and it is a matter of course that it is possible to partially replace or combine configurations described in different embodiments. In Embodiment 2 and subsequent embodiments, descriptions of common matters with Embodiment 1 will be omitted, and only different points will be described. In particular, similar actions and effects due to similar configurations will not be described sequentially for each embodiment.

In the following description, in a case where each embodiment is not particularly distinguished, they are simply referred to as an “integrated capacitor sheet of the present disclosure”, an “interposer of the present disclosure”, and a “semiconductor element of the present disclosure”. The shape, disposition, and the like of the integrated capacitor sheet, the interposer, and the semiconductor element of the present disclosure are not limited to the illustrated examples.

### Embodiment 1

An integrated capacitor sheet of the present disclosure includes a conductor layer and a porous layer provided on the conductor layer. The porous layer includes a capacitor portion having a structure of metal layer-dielectric layer-metal layer included in a porous structure of the porous layer, a through-hole portion in which the porous structure of the porous layer is filled with a conductor, and a porous insulating portion provided around the through-hole portion and in which the porous structure is not filled with the conductor. In addition, the conductor layer includes a metal conductor, a first via portion that penetrates a metal conductor directly below the through-hole portion and is connected to the through-hole portion, and a first insulating portion provided around the first via portion, and that insulates the first via portion and the metal conductor.

The integrated capacitor sheet having these configurations will be described below as an integrated capacitor sheet according to Embodiment 1 of the present disclosure.

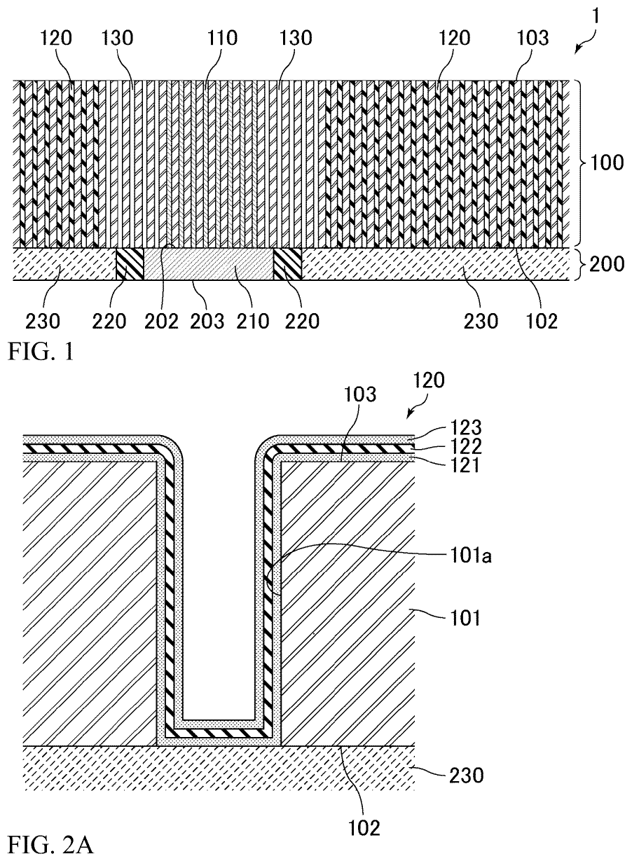

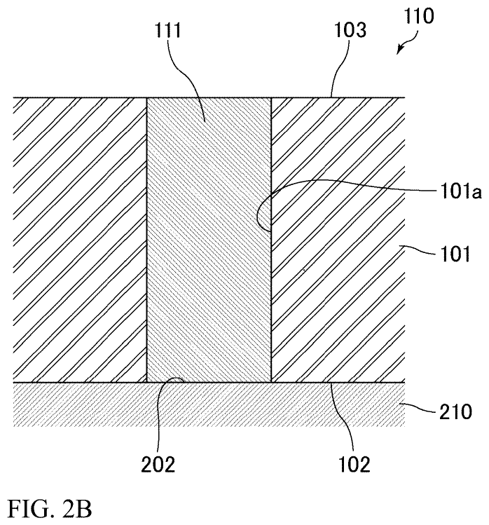

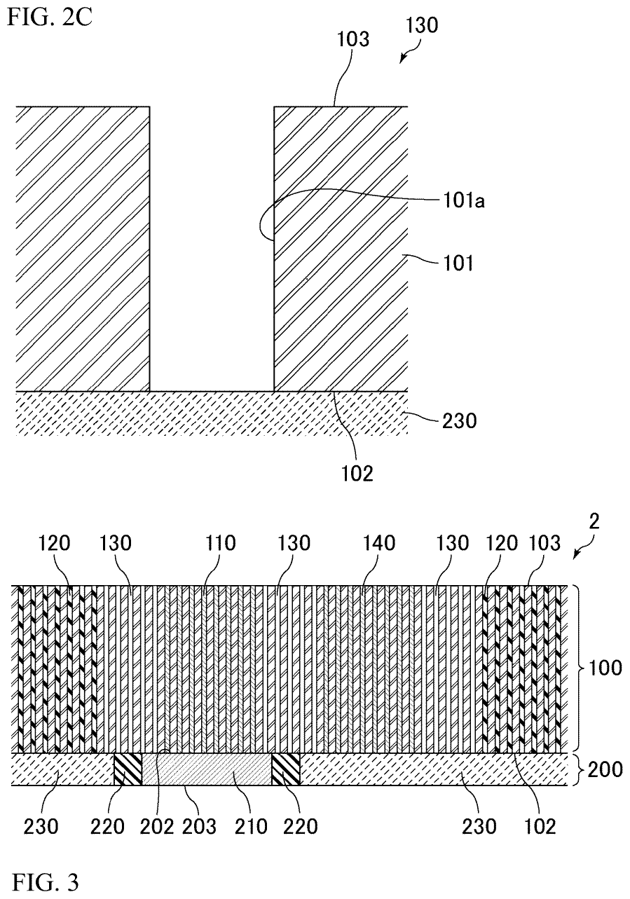

FIG. 1 is a cross-sectional view schematically illustrating an example of an integrated capacitor sheet according to Embodiment 1 of the present disclosure. FIG. 2A is an enlarged cross-sectional view of a capacitor portion, FIG. 2B is an enlarged cross-sectional view of a through-hole portion, and FIG. 2C is an enlarged cross-sectional view of a porous insulating portion.

An integrated capacitor sheet 1 illustrated in FIG. 1 includes a conductor layer 200 and a porous layer 100 provided on the conductor layer 200. In the hierarchy of the porous layer 100, a capacitor portion 120, a through-hole portion 110, and a porous insulating portion 130 are present.

The porous layer 100 may have a porous structure (Anodic Aluminum Oxide (AAO) structure) formed by anodizing aluminum. A wall surface 101a of the porous structure 101 is illustrated in FIGS. 2A, 2B, and 2C. The porous layer 100 includes a through-hole extending from a surface 103 of the porous layer to the conductor layer 200 in the thickness direction of the porous layer 100.

As illustrated in FIG. 2A, the capacitor portion 120 has a structure of a metal layer 121, a dielectric layer 122, and a metal layer 123 on the wall surface 101a of the porous structure 101. The structure is a metal-insulator-metal structure (hereinafter, also referred to as an MIM structure) and functions as a capacitor.

The MIM structure may be formed by atomic layer deposition (ALD).

The through-hole portion 110 has a structure that enables the conduction between a main surface 102 of the porous layer on the conductor layer side and a surface 103 of the porous layer (main surface of the porous layer on a side opposite to the conductor layer).

As illustrated in FIG. 2B, the through-hole portion 110 has a structure in which the porous structure 101 is filled with a conductor 111. In other words, it has a structure filled with the conductor 111 extending from the main surface 102 of the porous layer on the conductor layer side to the main surface 103 of the porous layer on a side opposite to the conductor layer.

When the porous structure 101 in the through-hole portion 110 is filled with the conductor 111, the through-hole portion 110 has a structure that enables the conduction between the main surface 102 of the porous layer 100 on the conductor layer side and the surface 103 of the porous layer. Copper or nickel may be used as the conductor 111.

As illustrated in FIG. 2C, the porous insulating portion 130 has a structure in which the porous structure 101 is not filled with a conductor. Since the porous structure is not filled with the conductor, the porous insulating portion 130 becomes an insulator. The porous insulating portion 130 is present between the through-hole portion 110 and the capacitor portion 120, and the through-hole portion 110 and the capacitor portion 120 are insulated so that there is no conduction between the through-hole portion 110 and the capacitor portion 120 at the hierarchy of the porous layer 100.

The conductor layer 200 is a layer that includes a metal conductor 230, a first via portion 210, and a first insulating portion 220 in the hierarchy. When the metal conductor 230 is in contact with the capacitor portion 120, one electrode (anode or cathode) of the capacitor portion 120 is extended from the metal conductor 230.

The metal constituting the metal conductor 230 may be one type or a plurality of types. For example, a multi-layer conductor layer having a three-layer structure of W—Al—Ti from the side closer to the porous layer can be used.

The first via portion 210 is a via provided by penetrating the metal conductor 230 directly below the through-hole portion 110. In other words, the first via portion 210 is a via that is provided along the direction where the through-hole portion 110 extends from the main surface 102 of the porous layer of the through-hole portion 110 on the conductor layer side, and is connected to the through-hole portion 110.

The first via portion may be made of metal. Copper may be used as the metal constituting the first via portion 210. Since the through-hole portion 110 and the first via portion 210 are connected to the main surface 202 of the conductor layer on the porous layer side, the through-hole portion 110 can be extended to the main surface 203 of the conductor layer on a side opposite to the porous layer. As a result, a structure is obtained in which the main surface 203 of the conductor layer on a side opposite to the porous layer is conducted to the surface 103 of the porous layer. That is, an integrated capacitor sheet can be obtained in which the conductor provided in the porous layer can be extended in the thickness direction.

A first insulating portion 220 that insulates the first via portion 210 and the metal conductor 230 is provided around the first via portion 210. The first insulating portion 220 may be made of a resin material, and the resin material that can be used as an insulating material can be used.

The metal conductor 230 is electrically connected to one electrode of the capacitor portion 120, but since the first via portion 210 and the metal conductor 230 are insulated by the first insulating portion 220, the capacitor portion 120 is electrically insulated from the first via portion 210 and the through-hole portion 110.

### Embodiment 2

An integrated capacitor sheet according to Embodiment 2 of the present disclosure further includes an extended electrode portion in which the porous structure of the porous layer is filled with a conductor and connected to the metal conductor of the conductor layer at the bottom portion.

FIG. 3 is a cross-sectional view schematically illustrating an example of an integrated capacitor sheet according to Embodiment 2 of the present disclosure.

An integrated capacitor sheet 2 illustrated in FIG. 3 includes an extended electrode portion 140 in the hierarchy of the porous layer 100.

The extended electrode portion 140 has a structure in which the porous structure is filled with a conductor. As a structure in the porous layer 100, the structure of the through-hole portion 110 and the structure of the extended electrode portion 140 are the same.

The extended electrode portion 140 is connected to the metal conductor 230 of the conductor layer 200 at the bottom portion. The extended electrode portion 140 and the through-hole portion 110 are different in that the first via portion 210 does not exist directly below the extended electrode portion 140 and that the metal conductor 230 exists.

In addition, as with the through-hole portion 110, the extended electrode portion 140 has a structure that enables the conduction between the main surface 102 of the porous layer 100 on the conductor layer side and the surface 103 of the porous layer.

The extended electrode portion 140 is connected to the metal conductor 230 of the conductor layer 200. Since the metal conductor 230 is in contact with the capacitor portion 120 and one electrode of the capacitor portion 120 is extended to the metal conductor 230, the extended electrode portion 140 is electrically connected to the capacitor portion 120 with the metal conductor 230 interposed therebetween. With this structure, one electrode of the capacitor portion 120 is extended to the surface 103 of the porous layer with the metal conductor 230 interposed therebetween.

That is, when the extended electrode portion 140 is provided, an extended position of the electrode from the capacitor portion 120 can be changed.

### Embodiment 3

An integrated capacitor sheet of Embodiment 3 of the present disclosure further includes a columnar metal electrode connected to the metal conductor of the conductor layer at the bottom portion, in the same hierarchy as that of the porous layer.

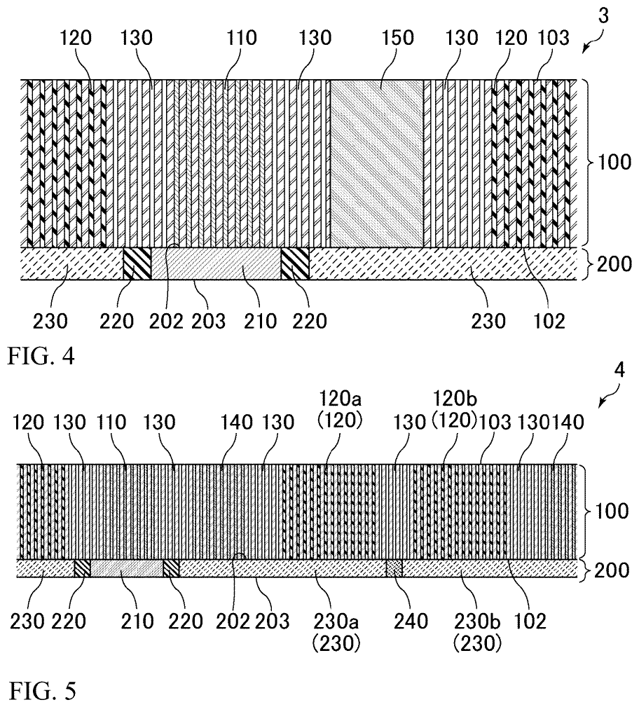

FIG. 4 is a cross-sectional view schematically illustrating an example of an integrated capacitor sheet according to Embodiment 3 of the present disclosure.

An integrated capacitor sheet 3 illustrated in FIG. 4 includes a columnar metal electrode 150 in the hierarchy of the porous layer 100.

The columnar metal electrode 150 is made of a dense metal rather than a porous structure. The columnar metal electrode 150 is on the same hierarchy as that of the porous layer (the same height as that of the porous layer in the integrated capacitor sheet), but is not a part of the porous layer.

The columnar metal electrode 150 is connected to the metal conductor 230 of the conductor layer 200 at the bottom portion. The first via portion 210 does not exist directly below the columnar metal electrode 150, and the metal conductor 230 exists.

In addition, as with the through-hole portion 110, the columnar metal electrode 150 has a structure that enables the conduction between the main surface 102 of the porous layer 100 on the conductor layer side and the surface 103 of the porous layer.

As the columnar metal electrode, aluminum that is not anodized may be used. In a step of anodizing aluminum to provide the porous layer, a part of the aluminum is masked to provide a portion that is not touched by an aqueous solution of an acid used for anodizing. As a result, the masked portion remains as a metal portion that is not anodized and does not become a porous layer. The remaining metal portion can be used as the columnar metal electrode 150.

When the columnar metal electrode 150 is provided, as with the case of providing the extended electrode portion 140, one electrode of the capacitor portion 120 is extended to the surface 103 of the porous layer with the metal conductor 230 interposed therebetween. That is, when the columnar metal electrode 150 is provided, an extended position of the electrode from the capacitor portion 120 can be changed.

### Embodiment 4

In an integrated capacitor sheet of Embodiment 4 of the present disclosure, the porous layer includes a plurality of capacitor portions, the metal conductor is connected to one of the metal layers of each capacitor portion, and the conductor layer further includes a third insulating portion that insulates a space between the metal conductors connected to different capacitor portions.

FIG. 5 is a cross-sectional view schematically illustrating an example of an integrated capacitor sheet according to Embodiment 4 of the present disclosure.

An integrated capacitor sheet 4 illustrated in FIG. 5 includes a plurality of capacitor portions 120 in the porous layer 100. The capacitor portion 120 illustrated at the center of the drawing is defined as a capacitor portion 120a, and the capacitor portion 120 illustrated on the right side of the drawing is defined as a capacitor portion 120b.

A plurality of capacitor portions 120 of the integrated capacitor sheet 4 may be disposed in an array form such as a lattice form or a zigzag form in a plan view.

The metal conductor 230 is connected to each capacitor portion 120. The metal conductor 230 illustrated at the center of the drawing is defined as a metal conductor 230a, and the metal conductor 230 illustrated on the right side of the drawing is defined as a metal conductor 230b. The capacitor portion 120a and the metal conductor 230a are connected, and the capacitor portion 120b and the metal conductor 230b are connected, but a third insulating portion 240 is provided between the metal conductor 230a and the metal conductor 230b, and the metal conductor 230a and the metal conductor 230b are electrically insulated. As a result, the capacitor portion 120a and the capacitor portion 120b are electrically isolated.

The material constituting the third insulating portion 240 is not limited, but it is suitably an inorganic insulating material, and SiO₂ can be used.

### Embodiment 5

An integrated capacitor sheet according to Embodiment 5 of the present disclosure further includes a substrate on which the conductor layer is placed.

The substrate further includes a base material, a second via portion that penetrates the base material directly below the first via portion and is integrated with the first via portion, and a second insulating portion that is provided around the second via portion and is integrated with the first insulating portion.

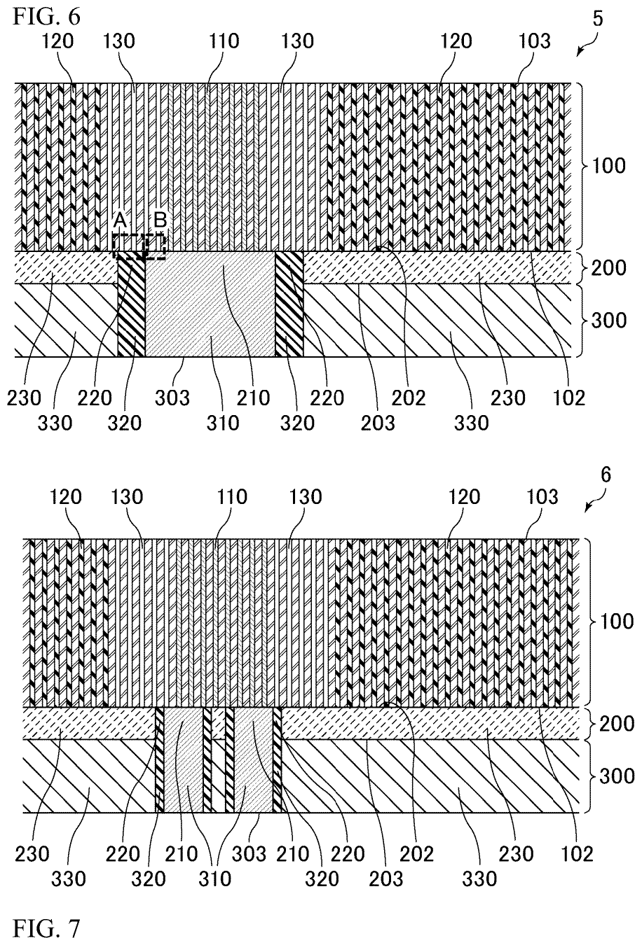

FIG. 6 is a cross-sectional view schematically illustrating an example of an integrated capacitor sheet according to Embodiment 5 of the present disclosure.

An integrated capacitor sheet 5 illustrated in FIG. 6 includes a substrate 300, and a conductor layer 200 is placed on the substrate 300. As the substrate 300, a silicon substrate, a glass substrate, an organic substrate, or the like can be used.

The substrate 300 is provided with a base material 330, a second via portion 310 that penetrates the base material 330, and a second insulating portion 320 provided around the second via portion 310.

A portion of the substrate 300 other than the through-hole, in which the second via portion 310 and the second insulating portion 320 are formed, is a base material 330.

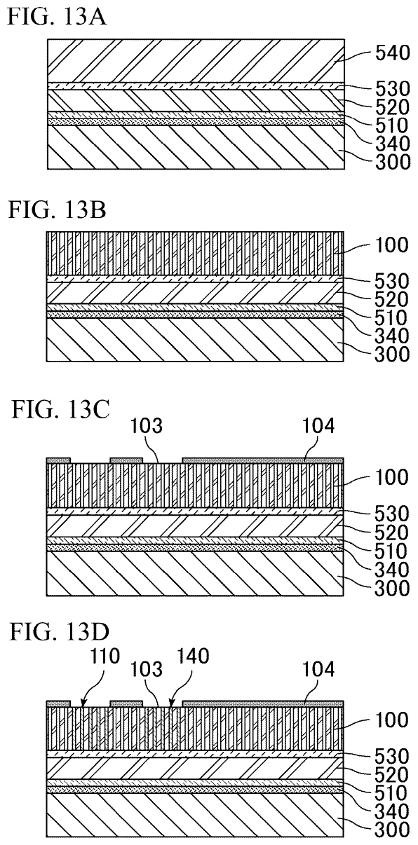

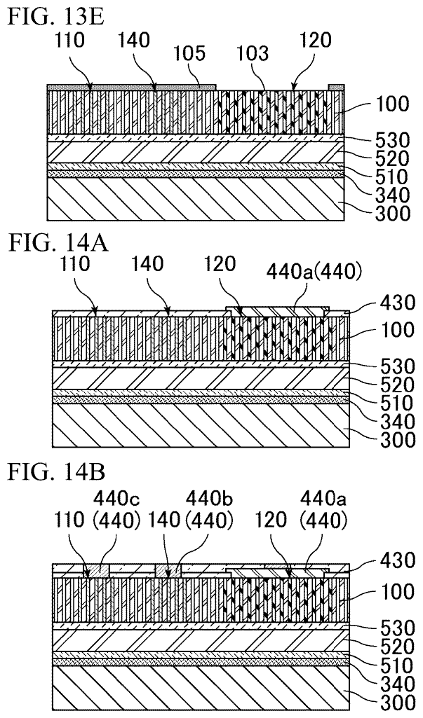

The base material 330 may be a semiconductor. In a case where the base material 330 is a semiconductor, the base material 330 can be made of a material such as silicon. In a case where the base material is not an insulator, an insulating layer may be provided between the base material 330 and the conductor layer 200, and SiO₂ may be used as the insulating layer. In the manufacturing step diagrams (FIG. 13A and later) described later, a diagram in which a SiO₂ layer 340 is provided between the base material 330 and the conductor layer 200 is illustrated.

The base material 330 may be an insulator. In a case where the base material 330 is an insulator, the base material 330 can be made of a material such as glass or an organic material.

The second via portion 310 is integrated with the first via portion 210. When the integrated capacitor sheet 5 of Embodiment 5 is manufactured, the first via portion 210 and the second via portion 310 can be simultaneously formed.

The second via portion 310 may be made of metal, and copper may be used as the metal constituting the second via portion 310. In a case where the material of the substrate 300 is silicon, a via, such as the second via portion 310, has a structure called a through silicon via (TSV: silicon through electrode).

The second insulating portion 320 is integrated with the first insulating portion 220. When the integrated capacitor sheet 5 of Embodiment 5 is manufactured, the first insulating portion 220 and the second insulating portion 320 can be simultaneously formed.

The second insulating portion 320 may be made of a resin material, and a resin material that can be used as an insulating material can be used.

Since the second via portion 310 is integrated with the first via portion 210, and the first via portion 210 is connected to the through-hole portion 110 directly below the through-hole portion 110, the through-hole portion 110 can be extended to the main surface 303 on a side opposite to the porous layer of the substrate. As a result, a structure is obtained in which the main surface 303 of the substrate on a side opposite to the porous layer is conducted to the surface 103 of the porous layer. That is, an integrated capacitor sheet can be obtained in which the conductor in the porous layer can be extended from the substrate in the thickness direction.

### Embodiment 6

An integrated capacitor sheet according to Embodiment 6 of the present disclosure is provided with a plurality of first via portions and second via portions for one through-hole portion.

FIG. 7 is a cross-sectional view schematically illustrating an example of an integrated capacitor sheet according to Embodiment 6 of the present disclosure.

An integrated capacitor sheet 6 illustrated in FIG. 7 is provided with four first via portions 210 and four second via portions 310 for one through-hole portion 110, and a first insulating portion 220 is provided around each first via portion 210, and a second insulating portion 320 is provided around each second via portion 310, respectively. FIG. 7 illustrates two first via portions 210 and two second via portions 310 visible on the front side, and the first insulating portion 220 and the second insulating portion 320 around these via portions.

With this structure, the cost (cost of the plating step) when forming the first via portion and the second via portion can be reduced.

### Embodiment 7

An integrated capacitor sheet according to Embodiment 7 of the present disclosure is provided with a plurality of first via portions and second via portions for a plurality of through-hole portions.

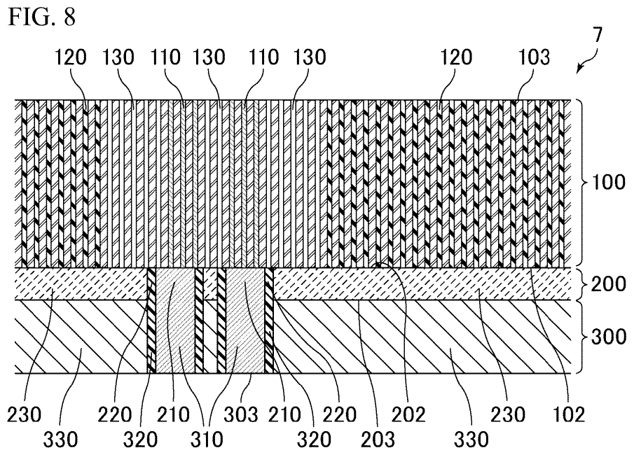

FIG. 8 is a cross-sectional view schematically illustrating an example of an integrated capacitor sheet according to Embodiment 7 of the present disclosure.

An integrated capacitor sheet 7 illustrated in FIG. 8 is provided with four first via portions 210 and four second via portions 310 for the four through-hole portions 110, and a first insulating portion 220 is provided around each first via portion 210, and a second insulating portion 320 is provided around each second via portion 310, respectively. FIG. 8 illustrates two through-hole portions 110, two first via portions 210 and two second via portions 310 visible on the front side, and the first insulating portion 220 and the second insulating portion 320 around these via portions.

With this structure, the resistance values of the through-hole portion 110, the first via portion 210, and the second via portion 310 can be reduced, and the stress applied to one through-hole portion 110 can be reduced.

### Embodiment 8

An integrated capacitor sheet according to Embodiment 8 of the present disclosure is provided with a third via portion formed by filling with the conductive paste.

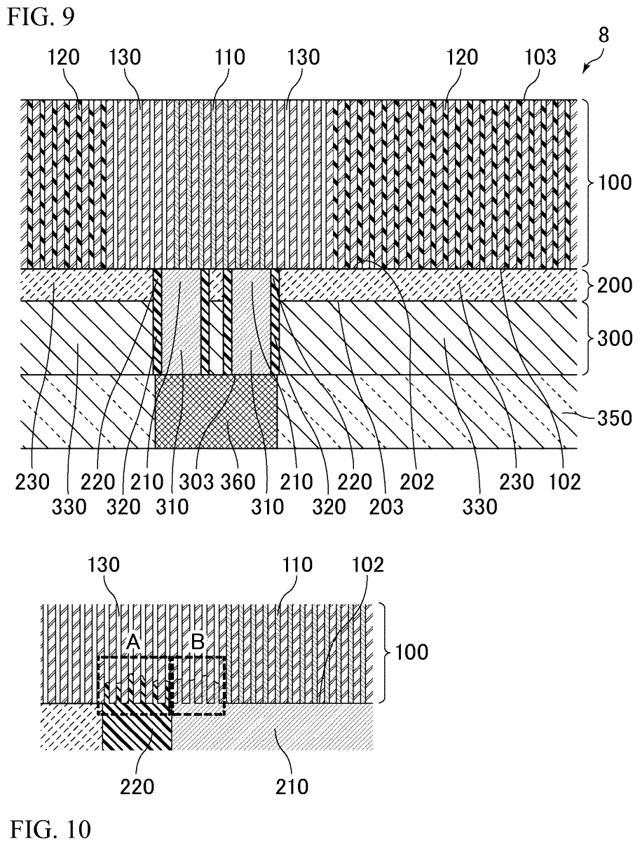

FIG. 9 is a cross-sectional view schematically illustrating an example of an integrated capacitor sheet according to Embodiment 8 of the present disclosure.

An integrated capacitor sheet 8 illustrated in FIG. 9 is further provided with a substrate side resin layer 350 under the substrate 300 in the integrated capacitor sheet 6 illustrated in FIG. 7. A third via portion 360 formed by filling an opening provided in the substrate side resin layer 350 with a conductive paste is included.

Since the third via portion 360 is connected to the second via portion 310 provided on the substrate 300, the third via portion 360 is connected to the through-hole portion 110 with the second via portion 310 and the first via portion 210 interposed therebetween.

The through-hole portion 110 is extended to the surface of the substrate side resin layer 350 (the main surface of the substrate side resin layer on a side opposite to the substrate).

As the material of the substrate side resin layer, for example, Ajinomoto Build-up Film (ABF (registered trademark)) can be used.

### [Common Matters of Embodiments 1 to 8]

In any of the integrated capacitor sheets of the present disclosure, a part of the first insulating portion may enter the porous layer adjacent to the first insulating portion.

In addition, a part of the first via portion may enter the porous layer adjacent to the first via portion.

FIG. 10 is an enlarged view of a portion including a region A and a region B surrounded by a dotted line in FIG. 6.

FIG. 10 schematically illustrates a state where a part of the first insulating portion 220 (resin material) enters the porous structure of the porous insulating portion 130 in the porous layer 100 in the region A. In addition, in the region B, a state where a part of the first via portion 210 (metal) enters the porous structure of the porous insulating portion 130 in the porous layer 100 is schematically illustrated.

When the first insulating portion 220 enters the porous layer 100, the coupling between the first insulating portion 220 and the porous layer 100 becomes stronger, and the connection reliability of the integrated capacitor sheet is improved.

Similarly, when the first via portion 210 enters the porous layer 100, the coupling between the first via portion 210 and the porous layer 100 becomes stronger, and the connection reliability of the integrated capacitor sheet is improved.

The position where the first insulating portion 220 and the first via portion 210 enter the porous layer 100 is not particularly limited, but since other materials easily enter the porous insulating portion 130, the first insulating portion 220 and the first via portion 210 may enter the porous insulating portion 130.

In addition, the entire first insulating portion 220 may be in contact with the porous insulating portion 130 over the entire main surface 102 of the porous layer on the conductor layer side, so that the first insulating portion 220 enters the porous layer 100 over the entire surface where the first insulating portion 220 is in contact with the porous layer 100 and exhibits an anchor effect.

### [Interposer]

Next, an example of an interposer of the present disclosure will be described.

An interposer of the present disclosure includes the integrated capacitor sheet of the present disclosure and a rewiring layer disposed on at least one of the main surfaces of the integrated capacitor sheet. The rewiring layer may include an organic insulating layer.

The rewiring layer is a layer called a redistribution layer (RDL).

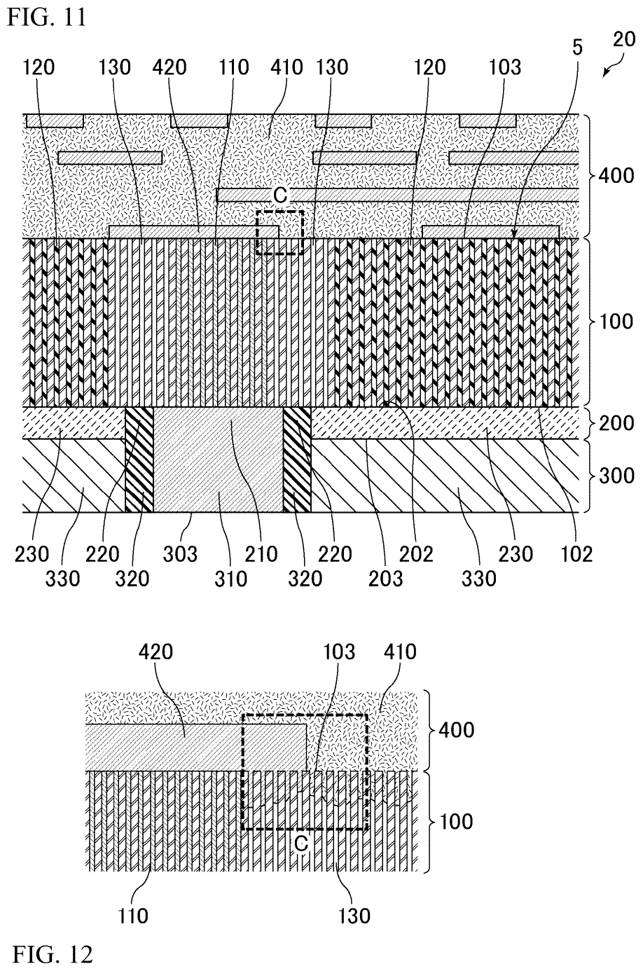

FIG. 11 is a cross-sectional view schematically illustrating an example of the interposer of the present disclosure.

An interposer 20 illustrated in FIG. 11 includes the integrated capacitor sheet 5 illustrated in FIG. 6 and a rewiring layer 400. The rewiring layer 400 is disposed on the surface 103 of the porous layer provided in the integrated capacitor sheet 5.

The rewiring layer 400 includes an organic insulating layer 410 and a wiring 420, and the wiring 420 is electrically connected to the through-hole portion 110 or the capacitor portion 120. The position, interval, and the like of the electrodes provided on the surface of the integrated capacitor sheet 5 are changed by the rewiring layer 400. As a result, it is easy to connect other semiconductor elements, such as logic, to each other.

Both the anode and the cathode of the capacitor portion 120 may be extended to the rewiring layer 400 by the wiring 420 provided on the rewiring layer 400, or only one of the anode and the cathode of the capacitor portion 120 may be extended to the rewiring layer 400. In a case where only one electrode is extended to the rewiring layer 400, the other electrode is assumed to be extended to a side opposite to the rewiring layer 400 (conductor layer side, substrate side).

FIG. 11 illustrates an example in which the rewiring layer is provided on the integrated capacitor sheet having the substrate, but the interposer of the present disclosure may be an interposer in which a rewiring layer is provided on an integrated capacitor sheet having no substrate (refer to Embodiments 1 to 4).

In addition, a rewiring layer may be provided on the main surface of the conductor layer on a side opposite to the porous layer or the main surface of the substrate on a side opposite to the porous layer. In addition, the rewiring layers may be provided on both main surfaces of the integrated capacitor sheet.

FIG. 11 illustrates an example in which the rewiring layer includes an organic insulating layer, but the rewiring layer may include an inorganic insulating layer and an organic insulating layer. That is, the rewiring layer may be a combination of an inorganic rewiring layer including an inorganic insulating layer and wiring in contact with the integrated capacitor sheet, and an organic rewiring layer including an organic insulating layer and wiring provided on the inorganic rewiring layer.

In the interposer of the present disclosure, a part of the rewiring layer may enter the porous layer adjacent to the rewiring layer.

FIG. 12 is an enlarged view of a portion including a region C surrounded by a dotted line in FIG. 11.

FIG. 12 schematically illustrates a state where a part of the organic insulating layer 410 and a part of the wiring 420 of the rewiring layer 400 enter the porous structure of the porous insulating portion 130 in the porous layer 100 in the region C.

In a case where the inorganic insulating layer in the rewiring layer is in contact with the porous layer, a part of the inorganic insulating layer may enter the porous layer adjacent to the rewiring layer.

When a part of the rewiring layer 400 enters the porous layer 100, the coupling between the rewiring layer 400 and the porous layer 100 becomes stronger, and the connection reliability of the interposer is improved.

The position where the rewiring layer 400 enters the porous layer 100 is not particularly limited, but since other materials easily enter the porous insulating portion 130, the rewiring layer 400 may enter the porous insulating portion 130.

### [Manufacturing Method of Integrated Capacitor Sheet and Interposer]

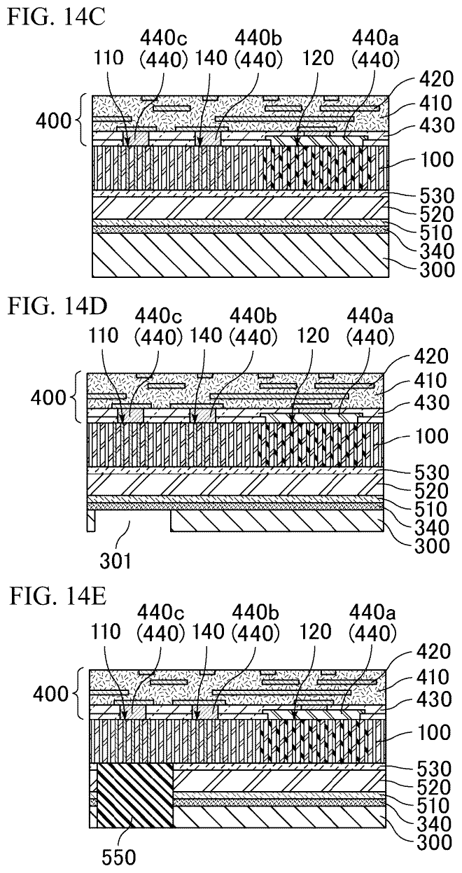

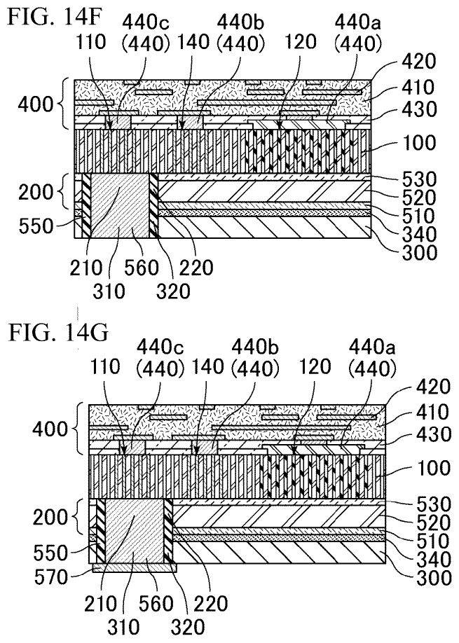

FIGS. 13A, 13B, 13C, 13D, and 13E are step diagrams schematically illustrating an example of a manufacturing step for an integrated capacitor sheet. FIGS. 14A, 14B, 14C, 14D, 14E, 14F, and 14G are step diagrams schematically illustrating an example of a manufacturing step for an integrated capacitor sheet and an interposer.

Hereinafter, the step of manufacturing the integrated capacitor sheet of the present disclosure and the step of manufacturing the interposer of the present disclosure using the manufactured integrated capacitor sheet will be sequentially described.

First, a substrate having a conductor layer laminated on the surface thereof is prepared.

FIG. 13A illustrates a structure in which a SiO₂ layer 340 is provided on a substrate 300 made of silicon, and conductor layers made of a Ti layer 510, an Al layer 520, a W layer 530, and an Al layer 540 are sequentially laminated on the SiO₂ layer 340.

The configuration of the conductor layers provided on the substrate 300 is not limited to the above configuration, but since the uppermost layer of the conductor layers is a layer as a porous layer, the uppermost layer may be an Al layer.

Next, a part or all of the conductor layers are anodized to form porous layers. FIG. 13B illustrates a state where the porous layer 100 having an AAO structure is formed as aluminum oxide by anodizing the uppermost Al layer 540 illustrated in FIG. 13A. The anodizing reaction stops at the W layer 530, and the W layer 530, which is a conductor layer, is exposed at the bottom portion of the porous structure of the porous layer 100.

In this step, when a part of the Al layer is masked to provide a portion that is not touched by the aqueous solution of the acid used for anodization, the masked portion is not anodized and remains as a metal portion that does not become a porous layer. The remaining metal portion can be used as the columnar metal electrode 150 (refer to FIG. 4).

Next, as illustrated in FIG. 13C, a first mask 104 is provided on the surface 103 of the porous layer. A SiO₂ film can be used as the first mask 104. The first mask 104 is patterned to be formed at a predetermined position on the surface 103 of the porous layer. In addition, the first mask 104 is not provided at the portion where the through-hole portion 110 is formed in the next step.

The first mask 104 may be a material that is formed without entering the porous structure and covers the surface 103 of the porous layer.

Next, as illustrated in FIG. 13D, the porous layer is filled with a conductor to form a through-hole portion 110. By filling the portion of the surface of the porous layer where the first mask 104 is not provided with the conductor, a through-hole portion 110 can be formed only at a predetermined portion of the porous layer. Filling the porous layer with the conductor may be performed by electrolytic plating. Copper or nickel may be used as the conductor.

In addition, the same applies to a step in a case where the extended electrode portion 140 is formed, and as with the case of forming the through-hole portion 110, the porous layer is filled with a conductor without providing the first mask 104 in the portion where the extended electrode portion 140 is formed.

The through-hole portion 110 and the extended electrode portion 140 are distinguished in roles in subsequent steps, but have the same configuration at this stage.

In a case where the porous layer filled with a conductor and the metal conductor are left in a connected state, without forming an opening, and without forming the first via portion and the first insulating portion in the conductor layer directly below the porous layer filled with the conductor in a later step, that portion becomes an extended electrode portion rather than a through-hole portion.

Next, after the first mask 104 is separated, as illustrated in FIG. 13E, a second mask 105 is provided on the surface of the porous layer. The SiO₂ film can be used as the second mask 105. The second mask 105 is patterned to be formed at a predetermined position on the surface 103 of the porous layer. The second mask 105 is not provided at the portion where the capacitor portion 120 is formed in the next step.

FIG. 13E also illustrates a step of forming the capacitor portion 120. A three-layer structure (MIM structure) of a metal layer, a dielectric layer, and a metal layer is formed by an ALD method at a portion of the surface 103 of the porous layer where the second mask 105 is not formed, and is defined as the capacitor portion 120. The metal layer, the dielectric layer, and the metal layer constituting the MIM structure may be materials that enter the porous structure and are formed along the wall surface of the porous structure.

In the steps so far, the portion where the porous layer is not filled with the conductor and the MIM structure is not formed is a portion where a structure in which the porous structure is not filled with the conductor remains, and is the porous insulating portion 130 (refer to FIGS. 1 and 2C). When the second mask 105 is separated, the integrated capacitor sheet of the present disclosure is obtained.

Next, a rewiring layer is provided on the surface of the porous layer. Hereinafter, an example in which an inorganic rewiring layer and an organic rewiring layer are provided as the rewiring layers will be described.

First, an inorganic rewiring layer is provided on the surface of the porous layer.

In a case where an inorganic rewiring layer is provided as the rewiring layer, an inorganic rewiring layer can be provided on the surface of the porous layer by performing steps such as forming a SiO₂ layer as an inorganic insulating layer, patterning, forming a wiring layer, and flattening by CMP.

FIGS. 14A and 14B illustrate a step of forming an inorganic rewiring layer.

The inorganic rewiring layer includes an inorganic insulating layer 430 and a wiring 440. In the wiring 440, a wiring 440a provided on the capacitor portion 120 and a wiring 440b provided on the extended electrode portion 140 become a cathode or an anode of the capacitor portion.

In addition, a wiring 440c provided on the through-hole portion 110 in the wiring 440 becomes a connection electrode of the through-hole portion.

The wiring 440a provided on the capacitor portion 120 may be an aluminum electrode, and the wiring 440b and the wiring 440c provided in other portions may be copper electrodes.

Subsequently, an organic rewiring layer is provided on the surface of the inorganic rewiring layer.

In a case where the organic rewiring layer is provided as the rewiring layer, the organic rewiring layer can be provided by performing steps of forming a resin layer as an organic insulating layer, patterning, and forming a wiring layer on the surface of the inorganic rewiring layer.

FIG. 14C illustrates a step of forming the organic rewiring layer.

The organic rewiring layer includes an organic insulating layer 410 and a wiring 420.

With the above steps, the rewiring layer 400 including the inorganic rewiring layer and the organic rewiring layer is provided.

Subsequently, an opening is formed on the substrate side, a via portion is formed in the opening, and an insulating portion is formed.

FIG. 14D illustrates a state where the substrate 300 is ground and thinned, and an opening 301 is provided at a predetermined position of the substrate 300. Forming the opening in the substrate can be performed by etching a material of the substrate (typically silicon).

Subsequently, as illustrated in FIG. 14E, the SiO₂ layer 340 and the conductor layer (Ti layer 510, Al layer 520, and W layer 530) are etched from the position of the opening 301, and the opening is formed at a position directly below the through-hole portion 110. The opening is filled with a resin 550.

Subsequently, as illustrated in FIG. 14F, an opening is provided in the resin 550, and the opening is filled with a via conductor 560. The via conductor 560 is connected to the through-hole portion 110, and the through-hole portion 110 is extended to the surface of the substrate 300.

The resin 550 provided in the steps so far becomes the first insulating portion 220 in the hierarchy of the conductor layer 200 and becomes the second insulating portion 320 in the hierarchy of the substrate 300. The first insulating portion 220 and the second insulating portion 320 are integrated with each other. In addition, the via conductor 560 becomes the first via portion 210 in the hierarchy of the conductor layer 200 and becomes the second via portion 310 in the hierarchy of the substrate 300. The first via portion 210 and the second via portion 310 are integrated with each other.

Through the above steps, the interposer of the present disclosure is obtained. In addition, a configuration in which the rewiring layer is removed from the obtained interposer is the integrated capacitor sheet of the present disclosure. That is, in the above steps, the interposer of the present disclosure including the integrated capacitor sheet of the present disclosure is obtained.

As illustrated in FIG. 14G, the via conductor 560 may be provided with an under bump metal (UBM 570) in order to improve solder bonding.

In addition, in the above steps, although the through-hole portion and the capacitor portion are formed in the substrate, the rewiring layer is provided, openings are provided in the substrate and the conductor layer to form the resin and via conductors (first via portion, second via portion, first insulating portion, and second insulating portion), the order may be changed. That is, after openings are provided in the substrate and the conductor layer to form the resin and the via conductors (first via portion, second via portion, first insulating portion, and second insulating portion), a through-hole portion and a capacitor portion may be formed in the substrate, and a rewiring layer may be provided.

Next, use examples of the integrated capacitor sheet and the interposer of the present disclosure will be described.

### Use Example 1

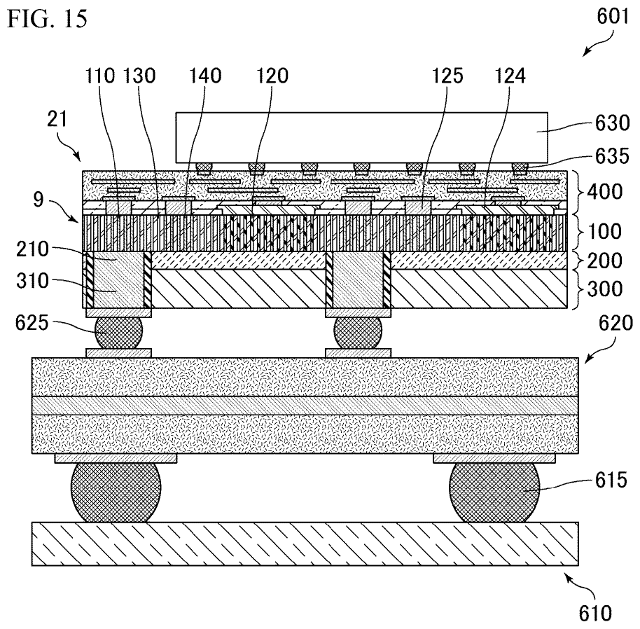

FIG. 15 is a cross-sectional view schematically illustrating a use example of the integrated capacitor sheet and the interposer.

FIG. 15 illustrates a mounting structure 601 in which a motherboard 610, a package substrate 620, an interposer 21, and a semiconductor component 630 are laminated from below. The motherboard 610 and the package substrate 620 are connected by a bump 615, the package substrate 620 and the interposer 21 are connected by a bump 625, and the interposer 21 and the semiconductor component 630 are connected by a bump 635.

The interposer 21 includes an integrated capacitor sheet 9 including the extended electrode portion 140 described in FIG. 3 and the substrate 300 described in FIG. 6.

An anode 124 of the capacitor portion 120 of the integrated capacitor sheet 9 is extended onto the capacitor portion 120, and a cathode 125 is extended onto the extended electrode portion 140 with the metal conductor 230 interposed therebetween. In other words, both the anode 124 and the cathode 125 of the capacitor portion 120 are extended on the rewiring layer 400 side.

Since there is no package substrate between the interposer 21 including the capacitor portion and the semiconductor component 630 such as logic, the distance between the capacitor and the semiconductor component can be short and the ESL can be reduced, so that the impedance characteristics in a high frequency region can be improved.

Since the first via portion 210 and the second via portion 310 are integrally provided directly below the through-hole portion 110 of the integrated capacitor sheet 9, the through-hole portion 110 is extended on the substrate side. The second via portion 310 is connected to the bump 625 connected to the package substrate 620.

That is, the conductor provided in the porous layer can be extended in the thickness direction and integrated with the power supply line on the substrate side.

### Use Example 2

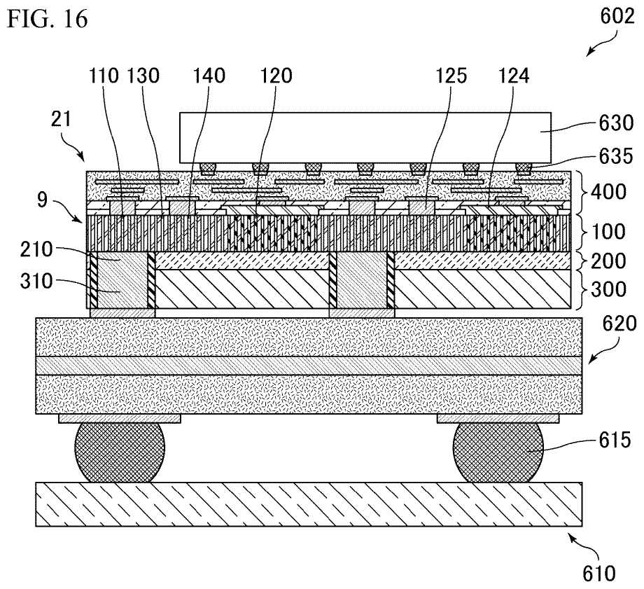

FIG. 16 is a cross-sectional view schematically illustrating another use example of the integrated capacitor sheet and the interposer.

A mounting structure 602 illustrated in FIG. 16 has substantially the same configuration as the mounting structure illustrated in FIG. 15, but has a bumpless connection structure in which the bump is not used for the connection between the package substrate 620 and the interposer 21.

Since ESL is likely to occur in the bump portion, the impedance characteristics can be improved by a bumpless connection.

In addition, when the bump is not used, the height of the entire mounting structure can be reduced, and this contributes to the reduction in height.

### Use Example 3

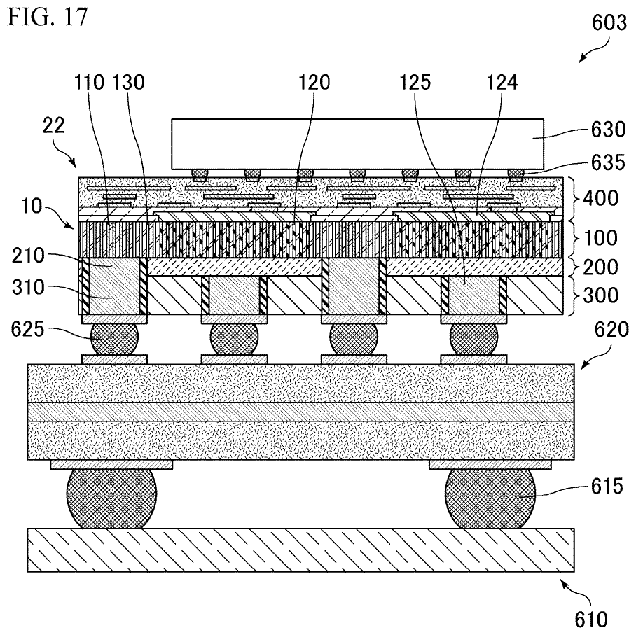

FIG. 17 is a cross-sectional view schematically illustrating another use example of the integrated capacitor sheet and the interposer.

An interposer 22 used for a mounting structure 603 illustrated in FIG. 17 includes an integrated capacitor sheet 10.

In the integrated capacitor sheet 10, the anode 124 of the capacitor portion 120 is extended above the capacitor portion 120, and the cathode 125 is extended under the capacitor portion 120 with the conductor layer 200 interposed therebetween.

When the integrated capacitor sheet and the interposer of the present disclosure are used, such a mounting structure can be employed, and thus, the degree of freedom in design is high.

The extension of the anode and the cathode from the capacitor portion 120 may be on different main surface sides, and when the structure is such that the extended surfaces of the anode and the cathode are different, it is easy to use as a coupling capacitor.

In addition, in the integrated capacitor sheet 10, since it is not necessary to extend one electrode of the capacitor portion 120 on the rewiring layer side, the extended electrode portion 140 need not be included.

### Use Example 4

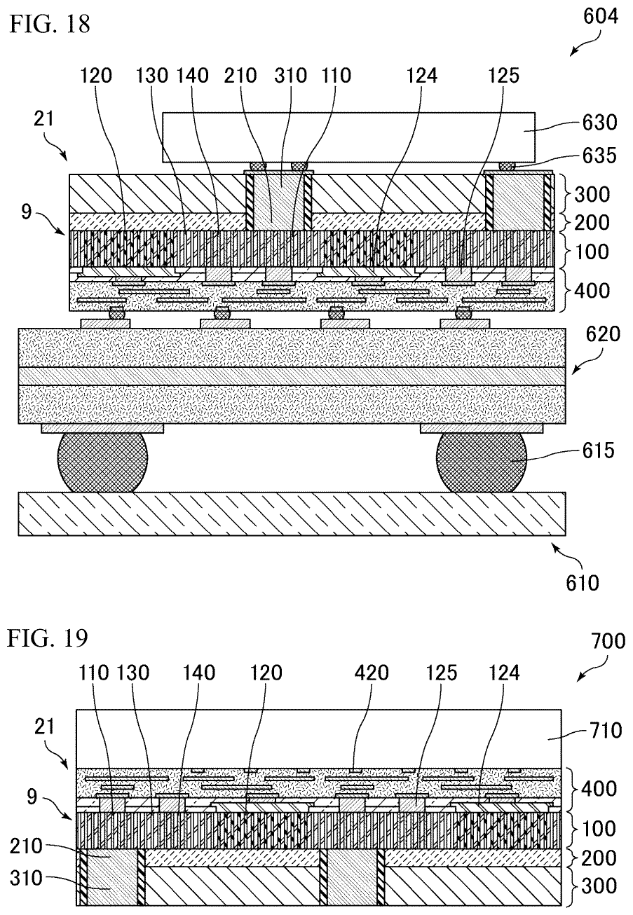

FIG. 18 is a cross-sectional view schematically illustrating another use example of the integrated capacitor sheet and the interposer.

In a mounting structure 604 illustrated in FIG. 18, the interposer 21 is used in an upside-down direction from that of the mounting structure illustrated in FIG. 15. In other words, the rewiring layer 400 is located on the package substrate 620 side, and the integrated capacitor sheet 9 is located on the semiconductor component 630 side.

In addition, although not illustrated, the rewiring layer may be used as the interposers provided on both surfaces of the integrated capacitor sheet. In this case, the configuration is [semiconductor component-(rewiring layer-integrated capacitor sheet-rewiring layer)-package substrate]. The portion of (rewiring layer-integrated capacitor sheet-rewiring layer) is an interposer.

When the integrated capacitor sheet and the interposer of the present disclosure are used, such a mounting structure can be employed, and thus, the degree of freedom in design is high.

### Semiconductor Element

Next, an example of a semiconductor element of the present disclosure will be described.

The semiconductor element of the present disclosure includes at least the integrated capacitor sheet of the present disclosure and the semiconductor portion in an integrated manner. The integrated capacitor sheet and the semiconductor portion may be integrated with each other with the rewiring layer interposed therebetween.

FIG. 19 is a cross-sectional view schematically illustrating an example of a semiconductor element of the present disclosure.

A semiconductor element 700 illustrated in FIG. 19 includes a portion (calculation portion) having a function of performing calculations as a semiconductor portion 710 and an interposer 21. The interposer 21 includes the integrated capacitor sheet 9 including the extended electrode portion 140 and the substrate 300, and the rewiring layer 400 described in Use Example 1.

The wiring 420 of the rewiring layer of the interposer 21 and the electrode of the semiconductor portion 710 are connected to each other and collectively sealed to form an integrated element. The semiconductor element 700 illustrated in FIG. 19 does not include a connection portion such as a solder bump, and has a laminated structure in which the wiring 420 of the rewiring layer 400 is continuous with an electrode of the semiconductor portion 710.

In other words, it can be said that the semiconductor element 700 which is one element partially includes the structure of the interposer of the present disclosure.

Unlike the structure of the semiconductor element 700 illustrated in FIG. 19, the semiconductor element of the present disclosure also includes a configuration in which an interposer and a semiconductor portion are connected to each other by having a micro bump, and the interposer and the semiconductor portion are collectively sealed and integrated with each other.

In addition, a configuration is included in which an integrated capacitor sheet and a semiconductor portion are included without including a rewiring layer, and the integrated capacitor sheet and the semiconductor portion are directly connected to each other, collectively sealed and integrated with each other.

In addition, as the function of the semiconductor portion, functions such as a calculation portion (logic), a storage portion (memory), and a control portion are included, and the function is not particularly limited.

The following contents are disclosed in the present specification.

<1> An integrated capacitor sheet including a conductor layer, and a porous layer provided on the conductor layer, in which the porous layer includes a capacitor portion having a structure of metal layer-dielectric layer-metal layer included in a porous structure of the porous layer, a through-hole portion in which the porous structure of the porous layer is filled with a conductor, and a porous insulating portion provided around the through-hole portion and in which the porous structure is not filled with the conductor, and the conductor layer includes a metal conductor, a first via portion that penetrates the metal conductor directly below the through-hole portion and is connected to the through-hole portion, and a first insulating portion that is provided around the first via portion and insulates the first via portion and the metal conductor.

<2> The integrated capacitor sheet according to <1>, in which the metal conductor is connected to one of the metal layers of the capacitor portion, and the porous layer further includes an extended electrode portion in which the porous structure of the porous layer is filled with the conductor, and that is connected to the metal conductor of the conductor layer at a bottom portion.

<3> The integrated capacitor sheet according to <1> or <2>, further including a columnar metal electrode connected to the metal conductor of the conductor layer at a bottom portion, in the same hierarchy as that of the porous layer.

<4> The integrated capacitor sheet according to any one of <1> to <3>, in which the porous layer includes a plurality of capacitor portions, the metal conductor is connected to one of the metal layers of each capacitor portion, and the conductor layer further includes a third insulating portion that insulates a space between the metal conductors connected to different capacitor portions.

<5> The integrated capacitor sheet according to any one of <1> to <4>, further including a substrate on which the conductor layer is placed, in which the substrate further includes a base material, a second via portion that penetrates the base material directly below the first via portion and is integrated with the first via portion, and a second insulating portion that is provided around the second via portion and is integrated with the first insulating portion.

<6> The integrated capacitor sheet according to <5>, further including an insulating layer between the base material and the conductor layer.

<7> The integrated capacitor sheet according to <5>, in which the base material is an insulator.

<8> The integrated capacitor sheet according to any one of <1> to <7>, in which a part of the first insulating portion enters the porous layer adjacent to the first insulating portion.

<9> The integrated capacitor sheet according to any one of <1> to <8>, in which a part of the first via portion enters the porous layer adjacent to the first via portion.

<10> An interposer including the integrated capacitor sheet according to any one of <1> to <9>, and a rewiring layer disposed on at least one of main surfaces of the integrated capacitor sheet.

<11> The interposer according to <10>, in which the rewiring layer includes an organic insulating layer.

<12> The interposer according to <10> or <11>, in which a part of the rewiring layer enters the porous layer adjacent to the rewiring layer.

<13> A semiconductor element including at least the integrated capacitor sheet according to any one of <1> to <9>, and a semiconductor portion in an integrated manner.

<14> The semiconductor element according to <13>, in which the integrated capacitor sheet according to any one of <1> to <9> and the semiconductor portion are integrated with each other with a rewiring layer interposed therebetween.
1, 2, 3, 4, 5, 6, 7, 8, 9, 10 Integrated capacitor sheet
20, 21, 22 Interposer
100 Porous layer
101 Porous structure
101a Wall surface of porous structure
102 Main surface of porous layer on conductor layer side
103 Surface of porous layer (main surface of porous layer on side opposite to conductor layer (substrate))
104 First mask (mask of porous layer surface)
105 Second mask (mask of porous layer surface)
110 Through-hole portion
111 Conductor
120, 120a, 120b Capacitor portion
121 Metal layer
122 Dielectric layer
123 Metal layer
124 Anode of capacitor
125 Cathode of capacitor
130 Porous insulating portion
140 Extended electrode portion (porous structure)
150 Columnar metal electrode (dense metal)
200 Conductor layer
202 Main surface of conductor layer on porous layer side
203 Main surface of conductor layer on side opposite to porous layer
210 First via portion
220 First insulating portion
230, 230a, 230b Metal conductor
240 Third insulating portion
300 Substrate
301 Opening of substrate
303 Main surface of substrate on side opposite to porous layer
310 Second via portion
320 Second insulating portion
330 Base material
340 SiO₂ layer
350 Substrate side resin layer
360 Third via portion
400 Rewiring layer
410 Organic insulating layer
420 Wiring
430 Inorganic insulating layer
440, 440a, 440b, 440c Wiring
510 Ti layer
520 Al layer
530 W layer
540 Al layer
550 Resin
560 Via conductor
570 UBM
601, 602, 603, 604 Mounting structure
610 Motherboard
615 Bump
620 Package substrate
625 Bump
630 Semiconductor component
635 Bump
700 Semiconductor element
710 Semiconductor portion

1. An integrated capacitor sheet comprising:
a conductor layer; and
a porous layer provided on the conductor layer, wherein
the porous layer includes
at least one capacitor portion each having a structure of metal layer-dielectric layer-metal layer included in a porous structure of the porous layer,
a through-hole portion having a conductor filled in the porous structure of the porous layer, and
a porous insulating portion provided around the through-hole portion and having the conductor not filled in the porous structure, and
the conductor layer includes
a metal conductor,
a first via portion penetrating the metal conductor directly below the through-hole portion and connected to the through-hole portion, and
a first insulating portion provided around the first via portion and insulating the first via portion and the metal conductor.

2. The integrated capacitor sheet according to claim 1, wherein
the metal conductor is connected to one of the metal layers of the capacitor portion, and
the porous layer further includes an extended electrode portion, the extended electrode portion having the conductor filled in the porous structure of the porous layer, and being connected to the metal conductor of the conductor layer at a bottom portion.

3. The integrated capacitor sheet according to claim 1, further comprising:
a columnar metal electrode connected to the metal conductor of the conductor layer at a bottom portion, in a same hierarchy as that of the porous layer.

4. The integrated capacitor sheet according to claim 1, wherein
the at least one capacitor portion comprises a plurality of capacitor portions,
the metal conductor is connected to one of the metal layers of each of the plurality of capacitor portions, and
the conductor layer further includes a third insulating portion insulating a space between the metal conductors connected to different ones of the capacitor portions.

5. The integrated capacitor sheet according to claim 1, further comprising:
a substrate on which the conductor layer is placed, wherein
the substrate further includes
a base material,
a second via portion penetrating the base material directly below the first via portion and integrated with the first via portion, and
a second insulating portion provided around the second via portion and integrated with the first insulating portion.

6. The integrated capacitor sheet according to claim 5, further comprising:
an insulating layer between the base material and the conductor layer.

7. The integrated capacitor sheet according to claim 5, wherein
the base material is an insulator.

8. The integrated capacitor sheet according to claim 1, wherein
a part of the first insulating portion enters the porous insulating portion adjacent to the first insulating portion.

9. The integrated capacitor sheet according to claim 1, wherein
a part of the first via portion enters the porous insulating portion adjacent to the first via portion.

10. An interposer comprising:
the integrated capacitor sheet according to claim 1; and
a rewiring layer disposed on at least one of main surfaces of the integrated capacitor sheet.

11. The interposer according to claim 10, wherein
the rewiring layer includes an organic insulating layer.

12. The interposer according to claim 10, wherein
a part of the rewiring layer enters the porous insulating portion adjacent to the rewiring layer.

13. A semiconductor element comprising at least the integrated capacitor sheet according to claim 1 and a semiconductor portion in an integrated manner.

14. The semiconductor element according to claim 13, wherein
the integrated capacitor sheet and the semiconductor portion are integrated with each other with a rewiring layer interposed therebetween.

15. The integrated capacitor sheet according to claim 2, further comprising:
a columnar metal electrode connected to the metal conductor of the conductor layer at a bottom portion, in a same hierarchy as that of the porous layer.

16. The integrated capacitor sheet according to claim 2, wherein
the at least one capacitor portion comprises a plurality of capacitor portions,
the metal conductor is connected to one of the metal layers of each of the plurality of capacitor portions, and
the conductor layer further includes a third insulating portion insulating a space between the metal conductors connected to different ones of the capacitor portions.

17. The integrated capacitor sheet according to claim 3, wherein
the at least one capacitor portion comprises a plurality of capacitor portions,
the metal conductor is connected to one of the metal layers of each of the plurality of capacitor portions, and
the conductor layer further includes a third insulating portion insulating a space between the metal conductors connected to different ones of the capacitor portions.

18. The integrated capacitor sheet according to claim 2, further comprising:
a substrate on which the conductor layer is placed, wherein
the substrate further includes
a base material,
a second via portion penetrating the base material directly below the first via portion and integrated with the first via portion, and
a second insulating portion provided around the second via portion and integrated with the first insulating portion.

19. The integrated capacitor sheet according to claim 3, further comprising:
a substrate on which the conductor layer is placed, wherein
the substrate further includes
a base material,
a second via portion penetrating the base material directly below the first via portion and integrated with the first via portion, and
a second insulating portion provided around the second via portion and integrated with the first insulating portion.

20. The integrated capacitor sheet according to claim 4, further comprising:
a substrate on which the conductor layer is placed, wherein
the substrate further includes
a base material,
a second via portion penetrating the base material directly below the first via portion and integrated with the first via portion, and
a second insulating portion provided around the second via portion and integrated with the first insulating portion.
